(19) United States
(12) Patent Application Publication
(10) Pub. No.: US 2025/0167740 A1
(43) Pub. Date: May 22, 2025

(54) CLASS D AMPLIFIER CAPABLE OF ANTI-CLIPPING

(71) Applicant: Richtek Technology Corporation, Hsinchu (TW)

(72) Inventors: Wen-Hsuan Chang, Pingtung (TW); Yi-Kuang Chen, Taichung (TW)

(21) Appl. No.: 18/644,121

(22) Filed: Apr. 24, 2024

(30) Foreign Application Priority Data
Nov. 21, 2023 (TW) 112145034

(51) Int. Cl. H03F 3/217

(52) U.S. Cl. CPC H03F 3/217; H03F 2200/03; H03F 2200/372

(57) ABSTRACT

A class-D amplifier for generating an output signal having PWM according to an input signal based on a DC voltage during a normal mode (NM) includes: a first integrator for generating a first integrated signal by integrating the difference of the input signal and a feedback signal during the NM; a final-stage integrator for generating a final-stage integrated signal by integrating the first integrated signal during the NM; a superposition circuit for generating a loop filter signal by buffering the final-stage integrated signal during the NM; and a modulation and driving circuit for generating the output signal by comparing the loop filter signal and a triangle wave. During a clipping mode, the first integrator enters a reset or a hold state, and the final-stage integrator enters the hold state, and the superposition circuit is configured to superimposes the final-stage integrated signal and a feedforward signal to generate the loop filter signal.

### CROSS REFERENCE

The present invention priority to TW patent application No. 112145034, filed on Nov. 21, 2023.

### BACKGROUND OF THE INVENTION

### Field of Invention

This invention relates to a Class D amplifier, particularly to a Class D amplifier that is capable of preventing clipping.

### Description of Related Art

Related prior arts to this case include: “Data processing system for clipping correction” (U.S. Pat. No. 8,081,022B2), “Pulse-width modulation amplifier and suppression of clipping therefor” (U.S. Pat. No. 7,315,202B2), “Amplifier apparatus” (U.S. Pat. No. 7,088,177B2).

FIG. 1 shows a block diagram of a Class D amplifier according to prior art. As shown in FIG. 1, in the prior art Class D amplifier 900, the integration circuit 180 includes a first integrator circuit 181 and a second integrator circuit 182. The first integrator circuit 181 integrates the difference between the input signal and the feedback signal to generate a first integrated signal, where the input signal includes a positive input signal Vip and a negative input signal Vin, and the feedback signal includes a negative feedback signal Sfbn and a positive feedback signal Sfbp. The first integrated signal includes a negative first integrated signal S8in and a positive first integrated signal S8ip. The second integrator circuit 182 integrates the first integrated signal S8in to generate a second integrated signal, which includes a negative second integrated signal S8ifn and a positive second integrated signal S8ifp. The modulation and driving circuit 1062 performs operations such as pulse width modulation on the second integrated signal (negative second integrated signal S8ifn and positive second integrated signal S8ifp) to control multiple switches within the modulation and driving circuit 1062 to generate a pulse-width modulated positive output signal Vop and negative output signal Von. The above positive output signal Vop and negative output signal Von are respectively fed through a feedback circuit 1041 and a feedback circuit 1042 to generate the negative feedback signal Sfbn and the positive feedback signal Sfbp, respectively.

A disadvantage of the aforementioned prior art is that when the input signal amplitude of the Class D amplifier is too high, it causes at least one integrator circuit within the integration circuit 180 to generate a clipped, saturated sinusoidal integrated signal, thereby causing noise or unpleasant popping sounds in the output signal of the Class D amplifier (e.g., the aforementioned positive output signal Vop and negative output signal Von).

In light of this, the present invention addresses the shortcomings of the aforementioned prior art by proposing a Class D amplifier capable of preventing clipping. By operating the reset and/or hold states of the integration circuit, as well as the operation of the feedforward architecture. The present invention therefore is able to prevent clipping as described in the prior art, making the output signal (e.g., sound) of the Class D amplifier closer to ideal and avoiding the production of popping sounds.

### SUMMARY OF THE INVENTION

From one perspective, the present invention provides a Class D amplifier for generating a pulse-width modulated output signal based on a DC voltage according to an input signal in a normal mode, comprising: a first-stage integrator circuit configured to integrate the difference between the input signal and a feedback signal in the normal mode to generate a first integrated signal, wherein the feedback signal is related to the output signal; a final-stage integrator circuit configured to integrate based on the first integrated signal to generate a final-stage integrated signal in the normal mode; a summing circuit configured to buffer the final-stage integrated signal to generate a loop filter signal in the normal mode; and a modulation and driving circuit configured to generate the output signal by comparing the loop filter signal with a triangle wave; wherein in a clipping mode, the first-stage integrator circuit enters a reset state or a hold state, the final-stage integrator circuit enters a hold state, and the summing circuit is configured to superimpose the final-stage integrated signal with a feedforward signal to generate the loop filter signal, wherein the feedforward signal is related to the input signal.

In one embodiment, the Class D amplifier further comprises: at least one intermediate integrator circuit configured to generate at least one intermediate integrated signal based on the first integrated signal, wherein the final-stage integrator circuit integrates based on the intermediate integrated signal to generate the final-stage integrated signal in the normal mode; wherein in the clipping mode, the intermediate integrator circuit enters a reset state or a hold state.

In one embodiment, the Class D amplifier further comprises a feedforward switch configured to conduct in the clipping mode to electrically connect the feedforward signal to the summing circuit, and to disconnect the feedforward signal from the summing circuit in the normal mode.

In one embodiment, in the normal mode, the summing circuit is further configured to superimpose the final-stage integrated signal with the feedforward signal to generate the loop filter signal.

In one embodiment, the Class D amplifier further comprises a clipping detection circuit configured to determine if the input signal will cause clipping based on the final-stage integrated signal, the loop filter signal, or the output signal, and to generate a clipping control signal when it is determined that the input signal will cause clipping, controlling the Class D amplifier to enter the clipping mode.

In one embodiment, the first-stage integrator circuit and/or the final-stage integrator circuit includes: an amplifier, an integration capacitor, and at least one state control switch, wherein the integration capacitor is coupled with the amplifier for corresponding integration operations; wherein one of at least one state control switch is connected in parallel with the integration capacitor to conduct in the clipping mode to reset the integration capacitor to enter a corresponding reset state; and/or wherein one of at least one state control switch is connected in series before an input of the amplifier, wherein the one state control switch is configured to disconnect in the clipping mode, thereby maintaining the state of the integration capacitor to enter a corresponding hold state.

In one embodiment, the first-stage integrator circuit, the intermediate integrator circuit, and the final-stage integrator circuit each include a digital integrator circuit configured to perform corresponding integration operations, wherein each of the input signal, the feedback signal, the feedforward signal, the final-stage integrated signal, and the loop filter signal corresponds to a digital signal.

In one embodiment, t the Class D amplifier further comprises a digital enable circuit configured to enable the superposition of the feedforward signal and the final-stage integrated signal in the clipping mode, and to disable the superposition of the feedforward signal and the final-stage integrated signal in the normal mode.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a block diagram of a Class D amplifier according to prior art.

FIG. 2 shows a block diagram of an embodiment of the Class D amplifier according to the present invention.

FIG. 3 shows a block diagram of an embodiment of the Class D amplifier according to the present invention.

FIG. 4 shows a block diagram of an embodiment of the Class D amplifier according to the present invention.

FIG. 5 shows a schematic diagram of a specific embodiment of the Class D amplifier according to the present invention.

FIG. 6 shows a schematic diagram of a specific embodiment of an integrator circuit in reset state in the Class D amplifier according to the present invention.

FIG. 7 shows a schematic diagram of a specific embodiment of an integrator circuit in hold state in the Class D amplifier according to the present invention.

FIG. 8 shows a schematic diagram of a specific embodiment of an integrator circuit in the reset state and/or the hold state in the Class D amplifier according to the present invention.

FIG. 9 shows a schematic diagram of a specific embodiment of the Class D amplifier according to the present invention.

FIG. 10 shows a schematic diagram of an embodiment of the intermediate integrator circuit in the Class D amplifier according to the present invention.

FIG. 11 a schematic diagram of a specific shows embodiment of the modulation and driving circuit in the Class D amplifier according to the present invention.

FIG. 12 shows a waveform diagram comparing the operation of a Class D amplifier according to prior art with an embodiment of the Class D amplifier according to the present invention.

FIG. 13 shows a schematic diagram of another specific embodiment of the Class D amplifier according to the present invention.

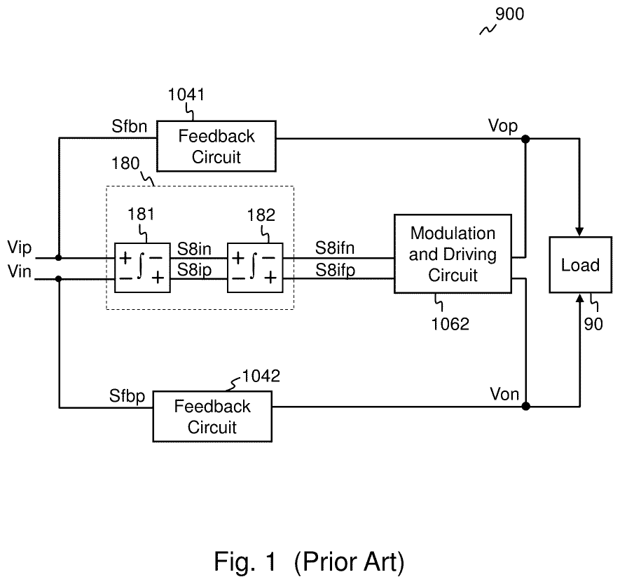

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

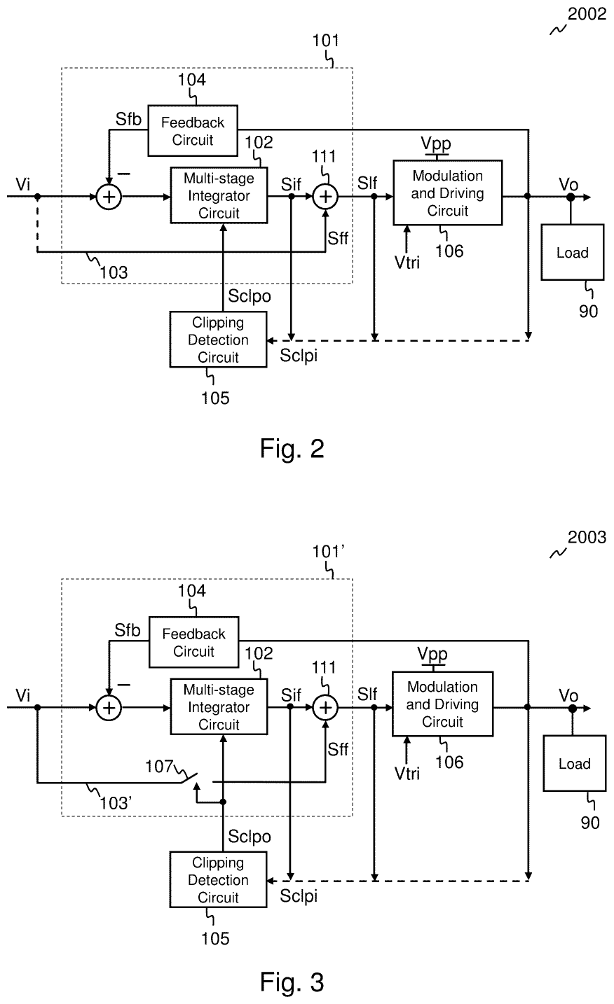

FIG. 2 shows a block diagram of an embodiment of the Class D amplifier according to the present invention. In one embodiment, as shown in FIG. 2, the Class D amplifier 2002 operates in a normal mode to generate a pulse-width modulated output signal Vo based on an input signal Vi and a DC voltage Vpp. The output signal Vo is configured to drive a load 90, which may be, for example but not limited to, a speaker or a linear resonant actuator (LRA). In one embodiment, the Class D amplifier 2002 includes a loop filter circuit 101 and a modulation and driving circuit 106. The loop filter circuit 101 generates a loop filter signal Slf based on the input signal Vi and the output signal Vo, and the modulation and driving circuit 106 controls switches within it to convert the DC voltage Vpp to generate a pulse-width modulated output signal Vo, based on the comparison between the loop filter signal Slf and a triangle wave Vtri. Details about the switches within the modulation and driving circuit 106 and the DC voltage Vpp will be described later.

In one embodiment, the loop filter circuit 101 includes a multi-stage integrator circuit 102, a feedback circuit 104, and a summing circuit 111. In one embodiment, in the normal mode, the multi-stage integrator circuit 102 integrates the difference between the input signal Vi and the feedback signal Sfb to generate a final-stage integrated signal Sif, wherein the summing circuit 111 buffers the final-stage integrated signal Sif to generate the loop filter signal Slf. In one embodiment, in a clipping mode, the multi-stage integrator circuit 102 enters a reset state or a hold state, and the summing circuit 111 superimposes the final-stage integrated signal Sif with a feedforward signal Sff to generate the loop filter signal Slf, thereby keeping the final-stage integrated signal Sif, the loop filter signal Slf, and the output signal Vo within a linear bias range to prevent clipping noise in the output signal Vo. In one embodiment, the feedback circuit 104 generates a feedback signal Sfb based on the output signal Vo. In one embodiment, the feedforward signal Sff is related to the input signal Vi, and in one embodiment, the feedforward signal Sff is generated through a feedforward path 103 from the input signal Vi, meaning the input signal Vi is the feedforward signal Sff.

In one embodiment, as shown in FIG. 2, the Class D amplifier 2002 further includes a clipping detection circuit 105. In one embodiment, the clipping detection circuit 105 determines whether the input signal Vi will cause clipping of the integrated signal or the output signal Vo based on the signals at any node along the signal path, and upon determining that the input signal Vi will cause clipping, the clipping detection circuit 105 generates a clipping control signal Sclpo, controlling the Class D amplifier 2002 to enter the clipping mode. In this embodiment, the clipping detection circuit 105 determines whether the input signal Vi will cause clipping based on a clipping detection signal Sclpi, and upon determining that the input signal Vi will cause clipping, the clipping detection circuit 105 generates a clipping control signal Sclpo, controlling the Class D amplifier 2002 to enter the clipping mode. In this embodiment, the clipping detection signal Sclpi is related, for example, to the final-stage integrated signal Sif, the loop filter signal Slf, or the output signal Vo. The operation details in the clipping mode will be described later.

FIG. 3 shows a block diagram of an embodiment of the Class D amplifier according to the present invention. The Class D amplifier 2003 in FIG. 3 is similar to the Class D amplifier 2002 in FIG. 2, with the difference that in the embodiment of FIG. 3, the Class D amplifier 2003 further includes a feedforward switch 107. In one embodiment, the feedforward switch 107 is turned on in the clipping mode to electrically connect the feedforward signal Sff to the summing circuit 111, and in the normal mode, the feedforward switch 107 disconnects the feedforward signal Sff from the summing circuit 111. In other words, in this embodiment, in the normal mode, the feedforward switch 107 is off, thereby disconnecting the electrical connection between the feedforward signal Sff and the summing circuit 111, and under this condition the summing circuit 111 only buffers the final-stage integrated signal Sif to generate the loop filter signal Slf. On the other hand, in the clipping mode, the clipping control signal Sclpo controls the feedforward switch 107 to conduct, and under this condition the summing circuit 111 is configured to superimpose the final-stage integrated signal Sif with the feedforward signal Sff, through the feedforward path 103′, to generate the loop filter signal Slf.

It is noteworthy that in the embodiment of FIG. 2, in the normal mode, the summing circuit 111 further superimposes the final-stage integrated signal Sif with the feedforward signal Sff to generate the loop filter signal Slf. In the embodiment of FIG. 3, since the feedforward switch 107 conducts only in the clipping mode, the summing circuit 111 only superimposes the final-stage integrated signal Sif with the feedforward signal Sff to generate the loop filter signal Slf in the clipping mode, meaning, from one perspective, the Class D amplifier in this embodiment does not modulate based on the feedforward signal in the normal mode. It should also be noted that both the embodiments in FIGS. 2 and 3 have the effect of preventing clipping according to the present invention, and the following will further illustrate the operational details of the specific embodiment including switch the feedforward as exemplified in FIG. 3.

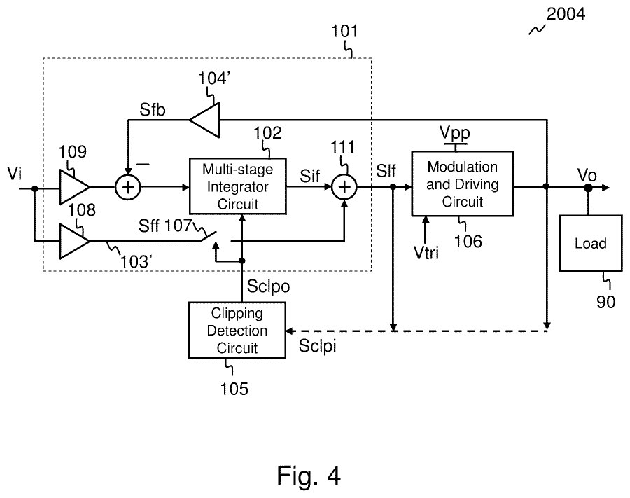

FIG. 4 shows a block diagram of an embodiment of the Class D amplifier according to the present invention. The Class D amplifier 2004 in FIG. 4 is a more specific embodiment corresponding to the Class D amplifier 2003 in FIG. 3. In the embodiment of FIG. 4, the feedback circuit 104 is configured as a buffer 104′, and the Class D amplifier 2004 further includes buffers 108 and 109. In one embodiment, the buffer 104′ buffers the output signal Vo to generate the feedback signal Sfb, and the buffers 108 and 109 buffer the input signal Vi.

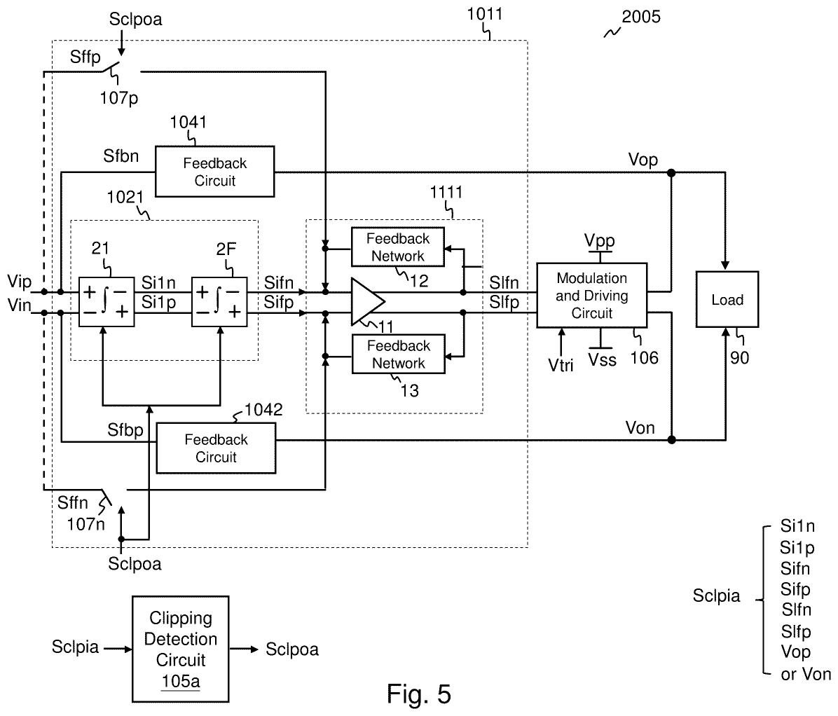

FIG. 5 shows a schematic diagram of a specific embodiment of the Class D amplifier according to the present invention. In one embodiment, in the Class D amplifier 2005 shown in FIG. 5, the input signal Vi includes a positive input signal Vip and a negative input signal Vin, the output signal Vo includes a positive output signal Vop and a negative output signal Von, and the feedforward switch includes a positive terminal feedforward switch 107p and a negative terminal feedforward switch 107n. In the embodiment of FIG. 5, the feedback circuit in the loop filter circuit 1011 includes feedback circuits 1041 and 1042, which are respectively configured to generate a negative feedback signal Sfbn and a positive feedback signal Sfbp based on the positive output signal Vop and the negative output signal Von, respectively. In the embodiment of FIG. 5, the multi-stage integrator circuit 1021 includes a first-stage integrator circuit 21 and a final-stage integrator circuit 2F, and the summing circuit 1111 includes an amplifier 11, feedback network 12, and feedback network 13.

As shown in FIG. 5, in one specific embodiment, in the normal mode, the first-stage integrator circuit 21 integrates the difference between the positive input signal Vip and the negative feedback signal Sfbn to generate the first negative integrated signal Si1n, and integrates the difference between the negative input signal Vin and the positive feedback signal Sfbp to generate the first positive integrated signal Si1p. The final-stage integrator circuit 2F subsequently integrates based on the first integrated signal to generate the final-stage integrated signal. The first integrated signal includes the first negative integrated signal Si1n and the first positive integrated signal Si1p, and the final-stage integrated signal includes the final-stage positive integrated signal Sifp and the final-stage negative integrated signal Sifn. From one perspective, the final-stage integrator circuit 2F integrates based on the first negative integrated signal Si1n to generate the final-stage negative integrated signal Sifn, and integrates based on the first positive integrated signal Si1p to generate the final-stage positive integrated signal Sifp.

In this embodiment, in the normal mode, both the positive terminal feedforward switch 107p and the negative terminal feedforward switch 107n are off, and the summing circuit 1111 buffers the final-stage negative integrated signal Sifn and the final-stage positive integrated signal Sifp to generate the negative loop filter signal Slin and the positive loop filter signal Slfp. In this embodiment, the modulation and driving circuit 106 generates the positive output signal Vop based on the comparison between the negative loop filter signal Slin and the triangle wave Vtri, and generates the negative output signal Von based on the comparison between the positive loop filter signal Slip and the triangle wave Vtri.

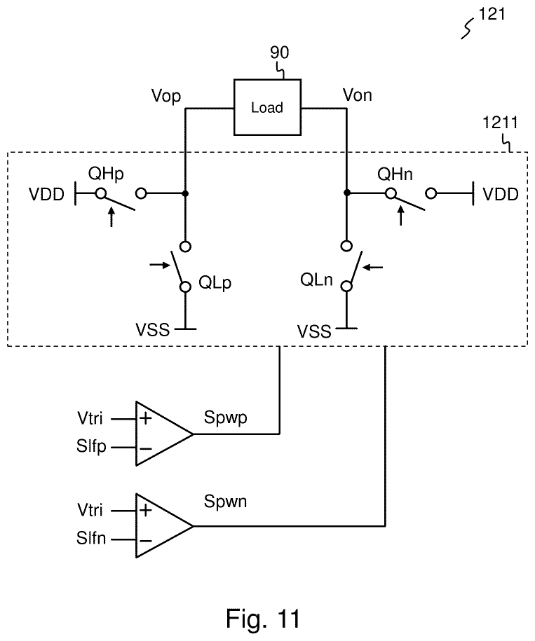

In one embodiment, the modulation and driving circuit may include a half-bridge power stage circuit or a full-bridge power stage circuit. Please also refer to FIG. 11, which shows a schematic diagram of a specific embodiment of the modulation and driving circuit in the Class D amplifier according to the present invention. In this embodiment, the modulation and driving circuit 121 generates the positive modulation signal Spwp based on the comparison between the positive loop filter signal Slfp and the triangle wave Vtri, and generates the negative modulation signal Spwn based on the comparison between the negative loop filter signal Slin and the triangle wave Vtri. Additionally, in this embodiment, the modulation and driving circuit 121 includes a full-bridge power stage circuit 1211, which includes upper bridge switches QHp, QHn, and lower bridge switches QLp, QLn. Specifically, the switches in the full-bridge power stage circuit 1211 are switched based on the positive modulation signal Spwp and the negative modulation signal Spwn, thereby converting the DC high reference voltage VDD and the DC low reference voltage VSS into the positive output signal Vop and the negative output signal Von. The aforementioned DC voltage Vpp, for example, corresponds to the DC high reference voltage VDD and the DC low reference voltage VSS.

Continuing with FIG. 5, in one embodiment, in the clipping mode, the first-stage integrator circuit 21 enters a reset state or a hold state, and the final-stage integrator circuit 2F enters a hold state (to be described later), and the clipping control signal Sclpoa controls the positive terminal feedforward switch 107p and the negative terminal feedforward switch 107n to conduct. In the clipping mode, the summing circuit 1111 is configured to superimpose the final-stage integrated signal with the feedforward signal related to the input signal to generate the loop filter signal. The feedforward signal includes the positive feedforward signal Sffp and the negative feedforward signal Sffn, and the loop filter signal includes the positive loop filter signal Slip and the negative loop filter signal Slfn. From one perspective, the summing circuit 1111 is configured to superimpose the final-stage negative integrated signal Sifn with the positive feedforward signal Sffp related to the positive input signal Vip to generate the negative loop filter signal Slin, and to superimpose the final-stage positive integrated signal Sifp with the negative feedforward signal Sffn related to the negative input signal Vin to generate the positive loop filter signal Slfp.

Continuing with FIG. 5, in one embodiment, the clipping detection circuit 105a in the Class D amplifier 2005 is configured to determine, based on the clipping detection signal Sclpia, whether the positive input signal Vip or the negative input signal Vin will cause clipping. If it is determined that the positive input signal Vip or the negative input signal Vin will cause clipping, a clipping control signal Sclpoa is generated to control the Class D amplifier 2005 to enter the clipping mode. In this embodiment, the clipping detection signal Sclpia is related to the first negative integrated signal Si1n, the first positive integrated signal Si1p, the final-stage negative integrated signal Sifn, the final-stage positive integrated signal Sifp, the negative loop filter signal Slfn, the positive loop filter signal Slip, the positive output signal Vop, or the negative output signal Von.

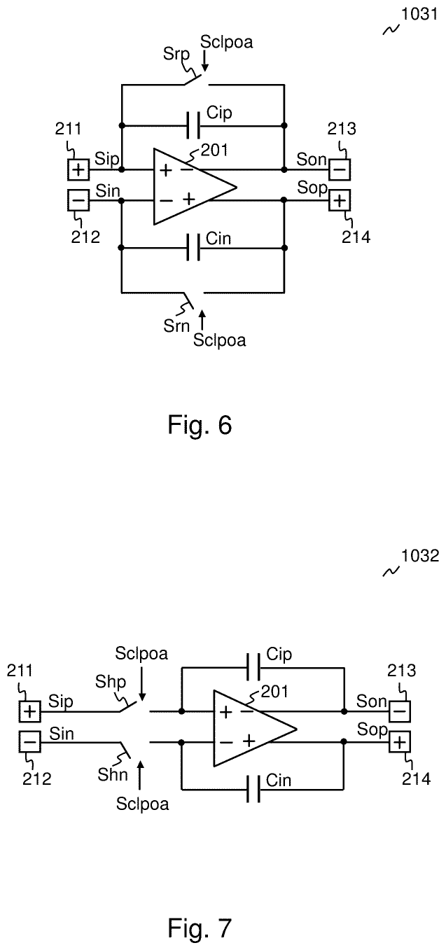

FIG. 6 shows a schematic diagram of an embodiment of an integrator circuit in reset state in the Class D amplifier according to the present invention. In one embodiment, the integrator circuit includes an amplifier, integration capacitors, and state control switches. In one embodiment, the first-stage integrator circuit 21 in FIG. 5 is configured as the integrator circuit 1031 in FIG. 6. As shown in FIG. 6, the integrator circuit 1031 includes an amplifier 201, integration capacitors Cip and Cin, and state control switches Srp and Srn. The integration capacitors Cip and Cin are coupled with the amplifier 201 to perform corresponding integration operations. Specifically, the integration capacitor Cip is coupled between the positive input and negative output of the amplifier 201, and the integration capacitor Cin is coupled between the negative input and positive output of the amplifier 201. In this embodiment, the state control switches Srp and Srn are respectively connected in parallel with the integration capacitors Cip and Cin to conduct in the clipping mode, thereby resetting the integration capacitors Cip and/or Cin to enter a corresponding reset state.

Please also refer to FIGS. 5 and 6. In one specific embodiment, in the normal mode, the state control switches Srp and Srn are off, and the amplifier 201 charge the integration capacitors Cip and Cin based on the positive input integration signal Sip and the negative input integration signal Sin, respectively, generating a negative output integration signal Son and a positive output integration signal Sop. When the clipping detection circuit 105a determines that the positive input signal Vip or the negative input signal Vin will cause clipping, it enters the clipping mode, and the clipping control signal Sclpoa controls the state control switches Srp and Srn to conduct, thereby resetting the integration capacitors Cip and/or Cin to enter a corresponding reset state.

It should be noted that when the first-stage integrator circuit 21 in FIG. 5 is configured as the integrator circuit 1031 in FIG. 6, the positive input integration signal Sip and the negative input integration signal Sin correspond to the positive input signal Vip and the negative input signal Vin, respectively. The negative output integration signal Son and the positive output integration signal Sop correspond to the first negative integrated signal Si1n and the first positive integrated signal Si1p, respectively. The positive input and negative input of amplifier 201 correspond to the positive input terminal 211 and the negative input terminal 212 of the integrator circuit 1031 (i.e., the first-stage integrator circuit 21), and the negative output and positive output of amplifier 201 correspond to the negative output terminal 213 and the positive output terminal 214 of the integrator circuit 1031 (i.e., the first-stage integrator circuit 21).

It should also be noted that in the embodiment in FIG. 6, by resetting the integration capacitors Cip and/or Cin in the clipping mode, it is possible to prevent the sinusoidal waveforms of the negative output integration signal Son and the positive output integration signal Sop from becoming saturated when the amplitude of the input signals of the Class D amplifier (such as the positive input signal Vip and the negative input signal Vin) is too high, thereby avoiding noise or popping sounds in the output signals (such as the positive output signal Vop and the negative output signal Von) of the Class D amplifier.

FIG. 7 shows a schematic diagram of an embodiment of an integrator circuit in a hold state in the Class D amplifier according to the present invention. In one embodiment, the first-stage integrator circuit 21 and/or the final-stage integrator circuit 2F in FIG. 5 are configured as the integrator circuit 1032 in FIG. 7. In one embodiment, the integrator circuit 1032 in FIG. 7 differs from the integrator circuit 1031 in FIG. 6 in that the integrator circuit 1032 includes state control switches Shp and Shn. In one embodiment, the state control switches Shp and Shn are respectively connected in series before the positive input and negative input of the amplifier 201 and are configured to conduct in the normal mode, thereby allowing the integration capacitors Cip and Cin to integrate, and to disconnect under the control of the clipping control signal Sclpoa in the clipping mode, to disconnect the signals (such as the positive input integration signal Sip and the negative input integration signal Sin) apart from the positive input and negative input of amplifier 201, thereby maintaining the state of the integration capacitors Cip and Cin to enter corresponding hold state. The remaining operational details of the integrator circuit 1032 in FIG. 7 can be inferred from the embodiment in FIG. 6 and are not further elaborated here.

It should be noted that when the first-stage integrator circuit 21 in FIG. 5 is configured as the integrator circuit 1032 in FIG. 7, the positive input integration signal Sip and the negative input integration signal Sin respectively correspond to the positive input signal Vip and the negative input signal Vin, the negative output integration signal Son and the positive output integration signal Sop respectively correspond to the first negative integrated signal Si1n and the first positive integrated signal Si1p, and the other corresponding relationships are similar to those in FIG. 6, and are not further elaborated here.

Additionally, it should be noted that when the final-stage integrator circuit 2F in FIG. 5 is configured as the integrator circuit 1032 in FIG. 7, the positive input integration signal Sip and the negative input integration signal Sin respectively correspond to the first negative integrated signal Sin and the first positive integrated signal Si1p, the negative output integration signal Son and the positive output integration signal Sop respectively correspond to the final-stage negative integrated signal Sifn and the final-stage positive integrated signal Sifp. One end of the state control switch Shp and one end of the state control switch Shn respectively correspond to the positive input terminal 211 and the negative input terminal 212 of the integrator circuit 1032 (i.e., final-stage integrator circuit 2F), and the negative output and positive output of amplifier 201 respectively correspond to the negative output terminal 213 and the positive output terminal 214 of the integrator circuit 1032 (i.e., final-stage integrator circuit 2F).

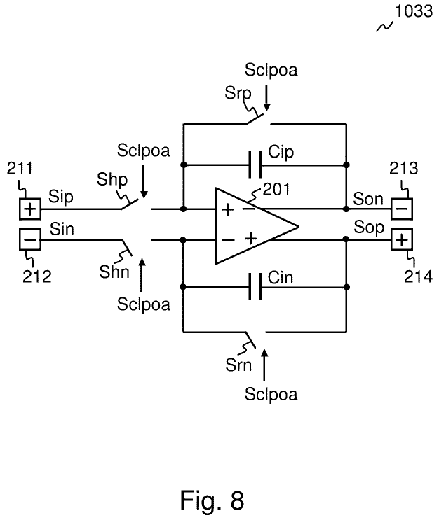

FIG. 8 shows a schematic diagram of an embodiment of an integrator circuit in the reset state and/or the hold state in the Class D amplifier according to the present invention. In one embodiment, the first-stage integrator circuit 21 and/or the final-stage integrator circuit 2F in FIG. 5 are configured as the integrator circuit 1033 in FIG. 8. As shown in FIG. 8, the integrator circuit 1033 includes the state control switches Srp and Srn as in the embodiment in FIG. 6, and the state control switches Shp and Shn as in the embodiment in FIG. 7. In this embodiment, when the first-stage integrator circuit 21 in FIG. 5 is configured as the integrator circuit 1033 in FIG. 8, in the normal mode, the state control switches Shp and Shn conduct, and the state control switches Srp and Srn are off, allowing integration of the integration capacitors Cip and Cin. On the other hand, in the clipping mode, the state control switches Shp and Shn switch to non-conductive, and the state control switches Srp and Srn are off to enter a corresponding hold state, or, in the clipping mode, the state control switches Srp and Srn switch to conduct, and the state control switches Shp and Shn remain conductive to enter a corresponding reset state.

On the other hand, in this embodiment, when the final-stage integrator circuit 2F in FIG. 5 is configured as the integrator circuit 1033 in FIG. 8. In the normal mode, the state control switches Shp and Shn conduct, and the state control switches Srp and Srn are off, allowing integration of the integration capacitors Cip and Cin. In the clipping mode, the state control switches Shp and Shn switch to non-conductive, and the state control switches Srp and Srn remain off to enter a corresponding hold state. The remaining operational details of the integrator circuit 1033 in FIG. 8 can be inferred from the embodiments in FIGS. 6 and 7 and are not further elaborated here.

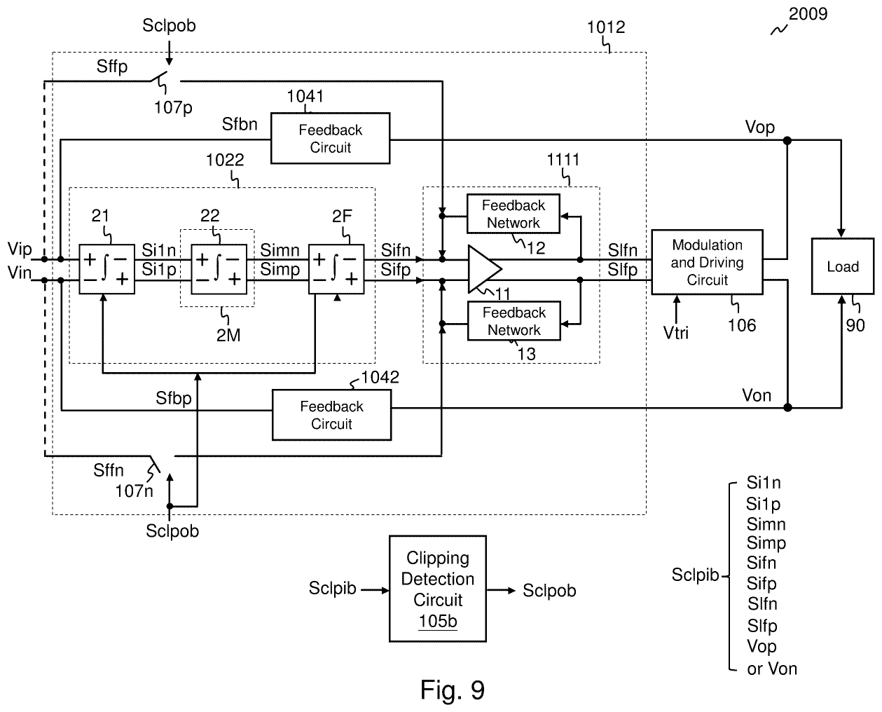

FIG. 9 shows a schematic diagram of a specific embodiment of the Class D amplifier according to the present invention. The Class D amplifier 2009 in FIG. 9 is similar to the Class D amplifier 2005 in FIG. 5, but differs in that in the embodiment of FIG. 9, the multi-stage integrator circuit 1022 in the loop filter circuit 1012 further includes at least one intermediate integrator circuit 2M, configured to generate corresponding at least one intermediate integrated signal based on the first integrated signal. Specifically, in this embodiment, the at least one intermediate integrator circuit 2M includes an intermediate integrator circuit 22 which generates corresponding negative intermediate integrated signals Simn and positive intermediate integrated signals Simp based on the first negative integrated signal Si1n and the first positive integrated signal Si1p. In this embodiment, the final-stage integrator circuit 2F integrates, in the normal mode, based on the negative intermediate integrated signal Simn to generate the final-stage negative integrated signal Sifn, and integrates based on the positive intermediate integrated signal Simp to generate the final-stage positive integrated signal Sifp. In the clipping mode, the intermediate integrator circuit 22 enters a reset state or a hold state. The reset and hold states of the intermediate integrator circuit 22 are as described in the previous embodiments.

In the embodiment of FIG. 9, the clipping detection circuit 105b determines based on the clipping detection signal Sclpib whether the positive input signal Vip or the negative input signal Vin will cause clipping, and upon determining that clipping will occur, generates a clipping control signal Sclpob to control the Class D amplifier 2009 to enter the clipping mode. Compared to the embodiment in FIG. 5, in this embodiment, the clipping detection signal Sclpib is further related to the negative intermediate integrated signal Simn or the positive intermediate integrated signal Simp. The remaining operational details of the Class D amplifier 2009 in FIG. 9 can be inferred from the embodiment in FIG. 5.

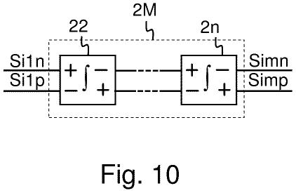

FIG. 10 shows a schematic diagram of an embodiment of an intermediate integrator circuit in the Class D amplifier according to the present invention. In one embodiment, as shown in FIG. 10, the at least one intermediate integrator circuit 2M in FIG. 9 includes intermediate integrator circuits 22 through 2n, where n is an integer greater than or equal to 2, meaning that the intermediate integrator circuit 2M can include one or multiple intermediate integrator circuits. In this embodiment, the intermediate integrator circuit 22 generates corresponding negative and positive intermediate integrated signals based on the first negative integrated signal Si1n and the first positive integrated signal Si1p. Subsequently through the integration in the intermediate integrator circuits between 22 and 2n, the last intermediate integrator circuit 2n generates corresponding negative intermediate integrated signal Simn and positive signal intermediate integrated Simp to the final-stage integrator circuit 2F. In one embodiment, in the clipping mode, all the intermediate integrator circuits in at least one intermediate integrator circuit 2M enter a reset state or a hold state.

It should be noted that, by controlling the feedforward signal and operating the first-stage integrator circuit (e.g., first-stage integrator circuit 21) and at least one intermediate integrator circuit 2M (e.g., intermediate integrator circuit 22) to be in corresponding reset states or hold states in the clipping mode, and operating the final-stage integrator circuit 2F in the hold state, the present invention resets or maintains the potentials of the integration capacitors in the integrator circuits. This prevents the integrated signals from clipping (saturating), thus avoiding unnecessary noise or popping sounds in the output signals (e.g., positive output signal Vop and negative output signal Von) of the Class D amplifier.

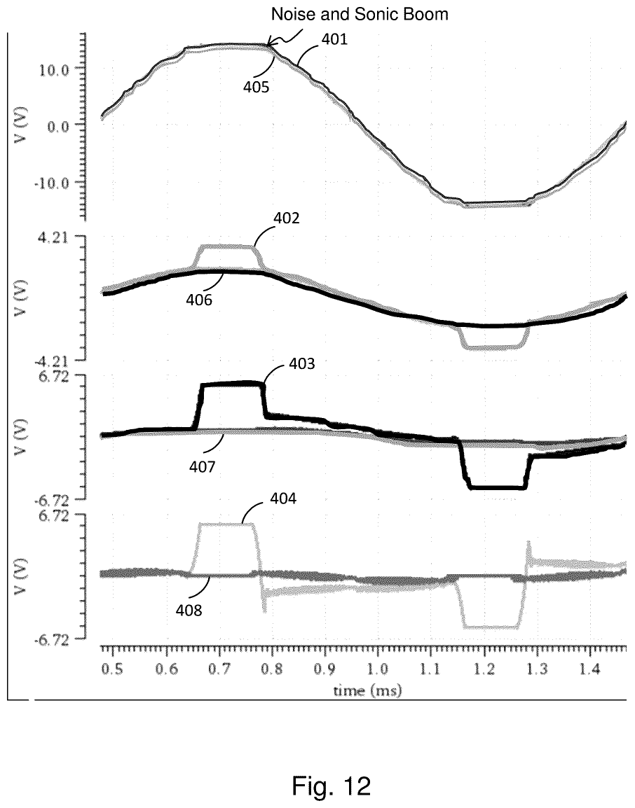

FIG. 12 shows waveform diagrams comparing the operation of a Class D amplifier according to prior art with an embodiment of the Class D amplifier according to the present invention. Waveform 401 is the output signal waveform of a Class D amplifier according to prior art, waveforms 402-404 are the waveforms of multiple integrated signals in the integrator circuit of the prior art Class D amplifier, waveform 405 is the output signal waveform of the Class D amplifier according to the present invention, and waveforms 406-408 are the waveforms of multiple integrated signals in the integrator circuit of the Class D amplifier according to the present invention. The waveforms in FIG. 12 indicate that in the prior art, when the input signal amplitude of the Class D amplifier is too high, it causes saturation of the multiple integrated signals to the positive or negative power supply (as shown in waveforms 402-404), leading to clipping, noise, and popping sounds in the output signal (as marked in the figure). However, in the present invention, by operating the integrator circuits in reset states or hold states in the clipping mode, resetting or maintaining the potentials of the integration capacitors in the integrator circuits, each integrated signal does not saturate (as shown in waveforms 406-408), thereby avoiding noise and popping sounds in the output signal.

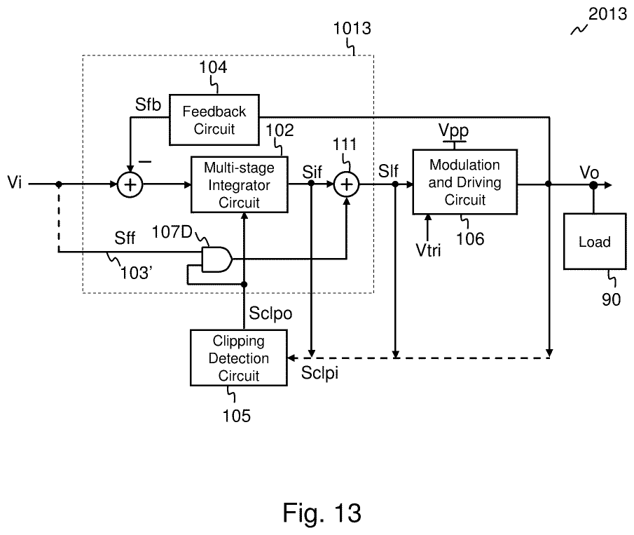

FIG. 13 shows another specific embodiment of the Class D amplifier according to the present invention. The Class D amplifier 2013 in FIG. 13 is similar to the Class D amplifier 2003 in FIG. 3, but differs in that in the embodiment of FIG. 13, the loop filter circuit 1013 of the Class D amplifier 2013 is implemented by digital circuitry. Specifically, in this embodiment, the input signal Vi, feedback signal Sfb, feedforward signal Sff, final-stage integrated signal Sif, and loop filter signal Slf are all digital signals, and both the feedback circuit 104 and the multi-stage integrator circuit 102 are also digital circuits, performing corresponding feedback and integration functions digitally. Specifically, the multi-stage integrator circuit 102 in FIG. 13 can correspond to the multi-stage integrator circuits in FIGS. 5, 9, and 10, i.e., corresponding to the multi-stage integrator circuit in FIG. 13. The first-stage, intermediate, and final-stage integrator circuits also correspond to the digital implementation of integration functions. In this embodiment, the feedforward path 103′ includes an enable logic circuit (e.g., corresponding to AND gate 107D) which is configured to enable or disable the superposition of the feedforward signal Sff and the final-stage integrated signal Sif based on the clipping control signal Sclpo.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be configured together, or, a part of one embodiment can be configured to replace a corresponding part of another embodiment. In view of the foregoing, the spirit of the present invention should cover all such and other modifications and variations, which should be interpreted to fall within the scope of the following claims and their equivalents.

What is claimed is:

1. A Class D amplifier for generating a pulse-width modulated output signal based on a DC voltage according to an input signal in a normal mode, comprising:
a first-stage integrator circuit configured to integrate the difference between the input signal and a feedback signal in the normal mode to generate a first integrated signal, wherein the feedback signal is related to the output signal;
a final-stage integrator circuit configured to integrate based on the first integrated signal to generate a final-stage integrated signal in the normal mode;
a summing circuit configured to buffer the final-stage integrated signal to generate a loop filter signal in the normal mode; and
a modulation and driving circuit configured to generate the output signal by comparing the loop filter signal with a triangle wave;
wherein in a clipping mode, the first-stage integrator circuit enters a reset state or a hold state, the final-stage integrator circuit enters a hold state, and the summing circuit is configured to superimpose the final-stage integrated signal with a feedforward signal to generate the loop filter signal, wherein the feedforward signal is related to the input signal.

2. The Class D amplifier of claim 1, further comprising:
at least one intermediate integrator circuit configured to generate at least one intermediate integrated signal based on the first integrated signal, wherein the final-stage integrator circuit integrates based on the intermediate integrated signal to generate the final-stage integrated signal in the normal mode;
wherein in the clipping mode, the intermediate integrator circuit enters a reset state or a hold state.

3. The Class D amplifier of claim 1, further comprising a feedforward switch configured to conduct in the clipping mode to electrically connect the feedforward signal to the summing circuit, and to disconnect the feedforward signal from the summing circuit in the normal mode.

4. The Class D amplifier of claim 1, wherein in the normal mode, the summing circuit is further configured to superimpose the final-stage integrated signal with the feedforward signal to generate the loop filter signal.

5. The Class D amplifier of claim 1, further comprising a clipping detection circuit configured to determine if the input signal will cause clipping based on the final-stage integrated signal, the loop filter signal, or the output signal, and to generate a clipping control signal when it is determined that the input signal will cause clipping, controlling the Class D amplifier to enter the clipping mode.

6. The Class D amplifier of claim 1, wherein the first-stage integrator circuit and/or the final-stage integrator circuit includes:
an amplifier, an integration capacitor, and at least one state control switch, wherein the integration capacitor is coupled with the amplifier for corresponding integration operations;
wherein one of at least one state control switch is connected in parallel with the integration capacitor to conduct in the clipping mode to reset the integration capacitor to enter a corresponding reset state; and/or
wherein one of at least one state control switch is connected in series before an input of the amplifier, wherein the one state control switch is configured to disconnect in the clipping mode, thereby maintaining the state of the integration capacitor to enter a corresponding hold state.

7. The Class D amplifier of claim 2, wherein the first-stage integrator circuit, the intermediate integrator circuit, and the final-stage integrator circuit each include a digital integrator circuit configured to perform corresponding integration operations, wherein each of the input signal, the feedback signal, the feedforward signal, the final-stage integrated signal, and the loop filter signal corresponds to a digital signal.

8. The Class D amplifier of claim 7, further comprising a digital enable circuit configured to enable the superposition of the feedforward signal and the final-stage integrated signal in the clipping mode, and to disable the superposition of the feedforward signal and the final-stage integrated signal in the normal mode.
